(19) United States
(12) Patent Application Publication
(10) Pub. No.: US 2007/0085716 A1
(43) Pub. Date: Apr. 19, 2007

(54) System and method for detecting matches of small edit distance

(75) Inventors: Ziv Bar-Yossef, Ra'anana (IL); Robert Krauthgamer, Albany, CA (US); Shanmugasundaram Ravikumar, Cupertino, CA (US); Jayram S. Thathachar, Morgan Hill, CA (US)

Correspondence Address: FREDERICK W. GIBB, III;GIBB INTELLECTUAL PROPERTY LAW FIRM, LLC, 2568-A RIVA ROAD, SUITE 304, ANNAPOLIS, MD, 21401, US

(73) Assignee: International Business Machines Corporation, Armonk, NY (US)

(21) Appl. No.: 11/241,468

(22) Filed: Sep. 30, 2005

(51) Int. Cl. H03M 7/30

(52) U.S. Cl. 341/87

(57) ABSTRACT

A system and method of approximating edit distance for a set of character strings in a database includes producing a representative sketch for each of the character strings; and approximating an edit distance between two selected character strings based only on the representative sketch for each of the selected character strings. The character strings may comprise text, wherein the method further comprises encoding positions of substrings in the text using anchors, wherein the anchors comprise identical substrings occurring in two input character strings at a nearby position. A set of anchors may be used in a correlated manner, wherein character strings with a sufficiently small edit distance are likely to use a same sequence of anchors. The character strings may be substantially non-repetitive. The representative sketch of a first character string is preferably constructed absent knowledge of a second character string. A size of the representative sketch may be constant.

### BACKGROUND

1. Field of the Invention

The embodiments of the invention generally relate to string comparison and matching, and, more particularly, to estimations of string matching edit distance.

2. Description of the Related Art

Many domains of data analysis deal with enormous collections of strings. For instance, in computational biology, DNA and protein data sets often comprise of sequences, which are written as strings over a suitable alphabet (in these cases, of sizes 4 and 20). In text processing and web searching, data sets comprise of documents, which are often regarded as a sequence (string) of words. In many scenarios, it is highly valuable to quickly detect similarities between strings, including in particular: (i) detection of motif; i.e., a collection of two or more strings in the data set that are similar to each other; and (ii) detection of a string in the data set which is similar to a given query string. Similarity between strings is often measured using a distance function.

Generally, string matching involves the comparison between two strings in order to determine how closely they resemble each other. One commonly used measure of string resemblance is “string edit distance”. Generally, the string edit distance measures the cost of editing one string such that it becomes identical to the other string. Edit distance (also referred to as the “Levenshtein” distance) is the minimum number of character insertions, deletions, and substitutions needed to transform one string to the other. Edit distance and its weighted variants (where edit operation are associated with different positive costs) are important primitives with numerous applications in areas such as computational biology and genomics, text processing, and web searching. Many of these application areas typically deal with large amounts of data ranging from a moderate number of extremely long strings, as in computational biology, to a large number of moderately long strings, as in text processing and web searching. Therefore methodologies for edit distance that are efficient in terms of computational resources (running time and/or storage space), even with modest approximation guarantees, are highly desirable.

Edit distance has been extensively studied for the past several years. An easy dynamic programming methodology computes the edit distance in quadratic time and the methodology can be made to run in linear space. However, the quadratic time methodology for computing the edit distance has generally improved by only a logarithmic factor, and even developing sub-quadratic time methodologies for approximating it within a modest factor has proved to be generally challenging. Accordingly, there remains a need to estimate the edit distance more efficiently and accurately.

### SUMMARY

In view of the foregoing, an embodiment of the invention provides a method of approximating edit distance for a set of character strings in a database, and a program storage device readable by computer, tangibly embodying a program of instructions executable by the computer to perform the method of approximating edit distance for a set of character strings in a database, wherein the method comprises producing a representative sketch for each of the character strings; and approximating an edit distance between two selected character strings based only on the representative sketch for each of the selected character strings.

The method may further comprise creating substrings from each of the character strings; identifying anchors in a particular character string; identifying a start position of the substrings of the particular character string according to the anchors; identifying a set of substrings according to the start position; encoding the set of substrings to produce the representative sketch; and using a Hamming distance between encodings of the two selected character strings to approximate the edit distance between the two selected character strings. Alternatively, the method may further comprise creating substrings from each of the character strings; encoding a start position of the substrings of the particular character string by rounding a numeric value of the start position to a nearest multiple of a predetermined number; identifying a set of substrings according to the start position; encoding the set of substrings to produce the representative sketch; and using a Hamming distance between encodings of the two selected character strings to approximate the edit distance between the two selected character strings.

In one embodiment the character strings comprise text, wherein the method further comprises encoding positions of substrings in the text using anchors, wherein the anchors comprise identical substrings occurring in two input character strings at a nearby position. The method may further comprise using a set of anchors in a correlated manner, wherein character strings with a sufficiently small edit distance are likely to use a same sequence of anchors. Moreover, the character strings may be substantially non-repetitive. Additionally, the representative sketch of a first character string is preferably constructed absent knowledge of a second character string. Also, according to one embodiment, a size of the representative sketch is constant. In one embodiment when the character strings comprise text, the method may further comprise approximating the edit distance between two selected character strings to within a constant factor on the order of n^{3/7}, wherein n comprises a size of the text. Furthermore, in another embodiment when the character strings comprise text, the method further comprises approximating the edit distance between two selected character strings to within a factor on the order of n^{1/3}, wherein n comprises a size of the text.

Another embodiment of the invention provides a system of approximating edit distance for a set of character strings in a database, wherein the system comprises a simulator adapted to produce a representative sketch for each of the character strings; and a processor adapted to approximate an edit distance between two selected character strings based only on the representative sketch for each of the selected character strings.

The processor may be further adapted to create substrings from each of the character strings; identify anchors in a particular character string; identify a start position of the substrings of the particular character string according to the anchors; identify a set of substrings according to the start position; encode the set of substrings to produce the representative sketch; and use a Hamming distance between encodings of the two selected character strings to approximate the edit distance between the two selected character strings.

Alternatively, the processor may be further adapted to create substrings from each of the character strings; encode a start position of the substrings of the particular character string by rounding a numeric value of the start position to a nearest multiple of a predetermined number; identify a set of substrings according to the start position; encode the set of substrings to produce the representative sketch; and use a Hamming distance between encodings of the two selected character strings to approximate the edit distance between the two selected character strings.

In one embodiment the character strings comprise text, wherein the system further comprises an encoder adapted to encode positions of substrings in the text using anchors, wherein the anchors comprise identical substrings occurring in two input character strings at a nearby position. Preferably the encoder is adapted to use a set of anchors in a correlated manner, wherein character strings with a sufficiently small edit distance are likely to use a same sequence of anchors. In one embodiment the character strings are substantially non-repetitive.

Preferably, the representative sketch of a first character string is constructed absent knowledge of a second character string. Moreover, a size of the representative sketch may be constant. When the character strings comprise text, the processor is adapted to approximate the edit distance between two selected character strings to within a constant factor on the order of n^{3/7}, wherein n comprises a size of the text. Additionally, in another embodiment when the character strings comprise text, the processor is adapted to approximate the edit distance between two selected character strings to within a factor on the order of n^{1/3}, wherein n comprises a size of the text.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a flow diagram illustrating a preferred method according to an embodiment of the invention;

FIG. 2 illustrates a schematic diagram of a system according to an embodiment of the invention; and

FIG. 3 illustrates a computer architecture diagram according to an embodiment of the invention.

### DETAILED DESCRIPTION OF PREFERRED EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

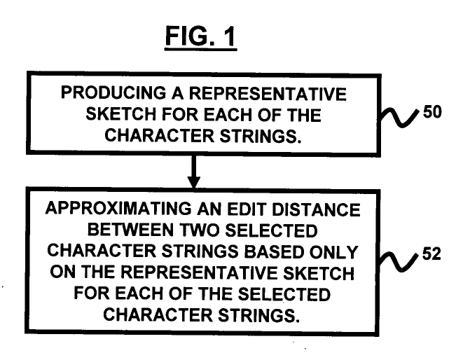

As mentioned, there remains a need to estimate the edit distance more efficiently and accurately. The embodiments of the invention achieve this by providing a technique for estimating the edit distance to within a guaranteed accuracy using only a short sketch corresponding to two strings. Specifically, the embodiments of the invention provide methodologies for approximating the edit distance, focusing on two powerful notions of efficiency that are applicable in dealing with massive data, namely, sketching methodologies and linear-time methodologies. Referring now to the drawings, and more particularly to FIGS. 1 through 3, there are shown preferred embodiments of the invention.

The embodiments of the invention provide a method of producing, for each string, a short sketch (e.g., signature or fingerprint), with the property that the edit distance between two strings can be inferred from looking only at their respective sketches. By applying these methods to large string collections (e.g., documents corpora or databases of known sequences), one can obtain faster and/or more accurate similarity detection systems. The embodiments of the invention are simple to implement in practice which represents a significant advantage over other schemes for edit distance.

One aspect of the embodiments of the invention is the encoding of the positions of substrings in the text using anchors. Anchors are themselves substrings which appear in the text, and the embodiments of the invention cleverly choose the set of anchors in a correlated manner to ensure that strings with small edit distance are likely to use the same sequence of anchors. Preferably, the strings are substantially “non-repetitive”, which improves the accuracy guarantees provided by the embodiments of the invention. However, the embodiments of the invention may also be useful for strings with mild repetitions of substrings.

In a large corpus it may be important to identify duplicate or near-duplicate documents. Most often, it is used to prevent multiple copies of the same document from affecting further processing or user queries. For example, in a large crawl of web pages, duplicates might bias rank procedures and clutter a query's result with many copies of the same page. The embodiments of the invention address this by computing a very short sketch of each document such that whether two documents are near-identical can be inferred from looking only at their respective sketches. The embodiments of the invention employ a well-defined measure of similarity (based on edit distance) rather than a heuristic measure based on common “shingles”. This improved accuracy may be particularly useful or necessary when (i) looking for plagiarism in documents or source code; and (ii) documents' contents is ordered (e.g., a ranked list of favorites).

In a database of one or more very long sequences it may be useful to identify repeating patterns (i.e., a collection of substrings that are similar to each other). In biological sequences, for instance, repeating patterns usually represent a certain functionality, and they are often used to identify genes and understand biological encoding. The embodiments of the invention address this by computing a short sketch of each substring (of a certain length) such that whether tow substrings are similar can be inferred from the respective sketches. Since these sketches are extremely short, the sketches provide an estimate that can be used as a preliminary filtering step when comparing all pairs of substrings (possibly in conjunction with other filtering methods that avoid considering all pairs of substrings using an even cruder estimate (i.e., the well-known q-gram method)). The relatively few substring pairs that pass the filtering step can then be examined using a more accurate (but less efficient) method, grouped into motifs, and/or abstracted into patterns (e.g., a generative model of the form of a probability matrix).

In another application, consider a client whose backup archive resides at a remote location, the communication to which has limited bandwidth (or high latency). In this case, it may be desirable to have the backup update procedure use the communication in proportion with the difference between the client's new version and the archive's older version. It is not too difficult to represent the entire data as one long string, and then the difference between two versions can be measured using the edit distance. The embodiments of the invention address this by allowing the archive to compute, in advance, a short sketch of each (overlapping) substring (of a certain length) of its string. When the backup update commences, the client partitions its string into a predetermined number of blocks, and sends to the archive only the sketch of each block. The archive can then determine for every block whether its edit distance to any substring of the archive is small or large. Blocks with no small edit distance to any of the archive's substrings are sent by the client in their entirety to the archive. For blocks with a small edit distance to some archive substring, the parties may uncover the differences between the client and the archive's version by further partitioning the block recursively (until some substring is determined to be equal to one in the archive, using standard fingerprints for equality testing).

The embodiments of the invention apply a reduction to the Hamming distance, then employs a sketching methodology. According to the embodiments of the invention, it is preferable to operate with the Hramming distance of strings over a larger alphabet (e.g., a sketch comprising 8 symbols in the alphabet {0, 1}⁶⁴). The Hamming distance sketch can be achieved, for example, by reducing it to the set-intersection problem and then utilizing a min- wise hashing methodology. Alternatively, the appropriate constants in the sketching methodology may be modified.

FIG. 1 illustrates a flow diagram of a method of approximating edit distance for a set of character strings in a database according to an embodiment of the invention, wherein the method comprises producing (50) a representative sketch for each of the character strings; and approximating (52) an edit distance between two selected character strings based only on the representative sketch for each of the selected character strings.

The method may fuirther comprise creating substrings from each of the character strings; identifying anchors in a particular character string; identifying a start position of the substrings of the particular character string according to the anchors; identifying a set of substrings according to the start position; encoding the set of substrings to produce the representative sketch; and using a Hamming distance between encodings of the two selected character strings to approximate the edit distance between the two selected character strings. Alternatively, the method may further comprise creating substrings from each of the character strings; encoding a start position of the substrings of the particular character string by rounding a numeric value of the start position to a nearest multiple of a predetermined number; identifying a set of substrings according to the start position; encoding the set of substrings to produce the representative sketch; and using a Hamming distance between encodings of the two selected character strings to approximate the edit distance between the two selected character strings.

In one embodiment the character strings comprise text, wherein the method further comprises encoding positions of substrings in the text using anchors, wherein the anchors comprise identical substrings occurring in two input character strings at a nearby position. The method may further comprise using a set of anchors in a correlated manner, wherein character strings with a sufficiently small edit distance are likely to use a same sequence of anchors.

Moreover, the character strings may be substantially non-repetitive. Additionally, the representative sketch of a first character string is preferably constructed absent knowledge of a second character string. Also, according to one embodiment, a size of the representative sketch is constant. In one embodiment when the character strings comprise text, the method may further comprise approximating the edit distance between two selected character strings to within a constant factor on the order of n^{3/7}, wherein n comprises a size of the text. Furthermore, in another embodiment when the character strings comprise text, the method further comprises approximating the edit distance between two selected character strings to within a factor on the order of n^{1/3}, wherein n comprises a size of the text.

The embodiments of the invention provide a framework design for efficient methodologies for the k vs. l gap version. of the edit distance problem: given two n-bit input strings with the promise that the edit distance is either at most k or more than l, decide which of the two cases holds. Such methodologies immediately yield approximation methodologies that are as efficient, with the approximation factor directly correlated with the gap between k and l, Specifically, the embodiments of the invention provide sketching methodologies and (quasi)-linear time methodologies for this gap problem. Additionally, the efficient methodologies provided by the embodiments of the invention may find applications (as building blocks) in a multitude of scenarios with voluminous data.

A sketching methodology for edit distance comprises two compression procedures and a reconstruction procedure, which operate in concert as follows. The compression procedures produce a fingerprint (sketch) from each of the input strings, and the reconstruction procedure uses solely the sketches to approximate the edit distance between the two strings. The key feature is that the sketch of each string is constructed without knowledge of the other string. The sketches are supposed to retain the minimum amount of information about the strings that is required to subsequently approximate the edit distance. The procedures are allowed to share random coins (e.g., they have access to a string of bits that are chosen at random in advance), and the main measure of complexity is the size of the sketches produced. In actual applications it is desirable that the procedures be efficient.

In contrast to Hamming distance, whose sketching complexity is well-understood, generally nothing was previously known about sketching of edit distance. In part, this is due to the fact that edit distance does not correspond to a vector space with a norm. In fact, it is not even known whether the edit distance metric space embeds into some normed space with low distortion. Besides being a very basic computational primitive for massive data sets, sketching is also related to (i) approximate nearest neighbor methodologies, (ii) protocols that are secure (i.e., leak no information), and (iii) the simultaneous messages communication model with public coins.

The first sketching methodology provided by the embodiments of the invention solves the k vs. O((kn)^{2/3}) gap problem, for any desired k≦\sqrt{n}. This methodology is ultra-efficient in terms of sketch size; i.e., it is constant. Moreover, this methodology is extremely appealing in applications where one expects most pairs of strings to be either quite similar or very dissimilar; e.g., duplicate elimination or a preprocessing filter in text corpora or in computational biology.

The second sketching methodology provided by the embodiments of the invention distinguishes a smaller gap and still produces a constant-sized sketch. It operates when the input strings are substantially “non-repetitive”. Again, mildly repetitive strings may also occur. Specifically, for any k≦\sqrt{n} and t≧1, if each of the length kt substrings of the inputs strings does not contain identical length t substrings, then the methodology solves the k vs. O(k²t) gap problem. Input instances for the Ulam metric, which is equivalent to the edit distance on strings that include distinct characters (e.g., permutations of {1, . . . , n}), are substantially non-repetitive with t=1 and any k≧1.

According to the embodiments of the invention, the overall structure of the first sketching methodology is a mapping of the original edit distance space into a Hamming space of low dimension. This mapping, which may be of independent interest, is achieved in two steps. First, the embodiments of the invention map each string to the multi-set of all its (overlapping) substrings. Each substring is annotated with a careful “encoding” of its position inside the input string. This encoding is insensitive to small “shifts”, and is thus useful in identifying substrings that are matched by an optimal alignment of the two strings. In the second step, the embodiments of the invention take the characteristic vector of the resulting set of substrings, which lies in a Hamming space of an exponentially high dimension, and map it into a Hamming space of constant dimension. The dependence on n in the gap in the first methodology is a consequence of the encoding method for the position of a substring. In essence, for each substring the embodiments of the invention produce an independent encoding of its position; while this conveniently separates the treatment of different substrings, the outcome is that one may fail to identify many matches, even in the presence of just one edit operation.

Accordingly, the embodiments of the invention overcome this by resorting to a method in which the encodings of the substring positions are correlated. Scanning the input string from left to right, the embodiments of the invention iteratively locate anchor substrings, which are identical substrings that occur in the two input strings at approximately the same position. The embodiments of the invention map each string to the set of substrings corresponding to the regions between successive anchors; the anchors are used for encoding the substring positions. As before, the resulting set of substrings is used to obtain an embedding in a Hamming space of constant dimension. Random permutations and min-wise hash functions (or efficient approximate implementations of them) are used to ensure that anchors are detected with high probability. This places a technical requirement that the input strings should not have too many identical substrings within the window where the embodiments of the invention might be looking for anchors, implying that the methodology is applicable to substantial non-repetitive strings. Again, mildly repetitive strings may also occur.

The embodiments of the invention provide linear time methodologies resulting in improved performance guarantees. The embodiments of the invention provide a methodology that provides a ρ-approximation if it produces a number that is at least the edit distance but no more than ρ times the edit distance. The time bounds refer to a RAM (random access memory) model with word size O(log n).

The embodiments of the invention provide a linear time methodology that achieve approximation ρ=n^{3/7}, which improves to ρ=n^{1/3} if the two strings are substantially non-repetitive. The best approximation factor that could be achieved in quasi-linear time with previous conventional techniques is n^{3/4}. The embodiments of the invention provide a very general framework for taking an approximation for the edit pattern matching and boosting it to a stronger approximation for edit distance. Here, edit pattern matching is the problem of finding all approximate matches of a pattern of size m in a text of size n, where an approximate match of the pattern is a sub-string of the text whose edit distance to the pattern is at most k. The embodiments of the invention demonstrate three instances of this paradigm. First, a simple instantiation of this framework already provides a methodology that solves the k vs. k² gap problem. This implies a \sqrt{n}-approximation methodology for edit distance, while the approximation provided directly by the edit pattern matching primitive that the embodiments of the invention rely on is only n. Using a non-trivial edit pattern matching methodology, the framework provided by the embodiments of the invention yields an enhanced methodology that solves the k vs. k^{7/4} gap problem, which implies the n^{3/7}-approximation described above. Under the assumption that the input strings are substantially non-repetitive, the third instantiation solves the k vs. k^{3/2} gap, yielding an n^{1/3}-approximation.

The embodiments of the invention provide methodologies for the k vs. l gap version of edit distance. Here, k is given as an input parameter to the methodology. The smaller the difference between k and l=l (n, k), the better the approximation achievable from these methodologies. To simplify the exposition, the embodiments of the invention make no attempt to optimize constants.

The embodiments of the invention deal with strings over a finite alphabet Σ. For simplicity, most of the statements refer to Boolean strings (i.e., Σ={0, 1}). Throughout, xy denotes the concatenation of two strings x and y. The empty string is denoted by ε. For integers i,j, the interval [i . . . j] denotes the set of integers {i, . . . , j} (which is empty if i>j); [i] is a shorthand for the interval [1 . . . i]. Here, if x∈Σⁿ is a string of length n and i∈[n], then x(i) is the i-th character of x. Similarly, x[i . . . j] denotes the substring obtained by projecting x on the positions in the set [i . . . j]∩[n]. If this set is empty, then x[i . . . j]=ε.

An edit operation on a string x ∈Σⁿ is either an insertion, a deletion, or a substitution of a character of x. The edit distance between x and y, denoted throughout by ED(x,y), is defined to be the minimum number of edit operations needed to transform x into y. A string x∈{0,1}ⁿ is called (t, l)-non-repetitive, if for any interval [i . . . j] of size l, the l substrings of x of length t whose left endpoints are in this interval and are distinct.

A sketching methodology is best viewed as a two-party communication protocol with public-coins and with one round of simultaneous messages. For example, in this model three players, Alice, Bob, and a referee, jointly compute a two-argument function ƒ : X×Y→Z. Alice is givenx x∈X and Bob is given y∈Y. Based on her input and based on randomness that is shared with Bob, Alice prepares a “sketch” s_{A}(x) and sends it to the referee; similarly, Bob sends a sketch s_{B}(X) to the referee. The referee uses the two sketches (and possibly the shared randomness) to compute the value of the function ƒ(x, y), or an estimate of it ƒ′(x, y). The error probability is defined as the maximum, over all inputs x in X, y in Y, of the probability that the estimate is wrong,ƒ′(x,y)≠ƒ(x,y), where the probability is over the shared randomness. The main measure of cost of a sketching methodology is the length of the sketches s_{A}(X) and s_{B}(Y) on the worst-case choice of inputs x, y.

Throughout, the embodiments of the invention seek methodologies whose error probability is some small constant; for example, ⅓. As usual, this error can be reduced to any value 0<δ<1, using O(log(1/67 )) simultaneous repetitions. In many applications, it is desirable that the three players are efficient (in time, space, etc.). The embodiments of the invention provide that a sketching methodology is t(n)-efficient, if the running time of each of the three players is O(t(n)), where n is the size of the player's input (x for Alice, y for Bob, and (s_{A}(x), s_{B}(Y)) for the referee). The case t(n)=O(n) is called linear-time, and t(n)=n*(log n)^{O(1)} is called quasi-linear time.

Next, the two sketching methodologies for solving gap edit distance problems are described in accordance with the embodiments of the invention. The underlying principle in both methodologies is the same: the two input strings have a small edit distance if and only if they share many sufficiently long substrings occurring at nearly the same position in both strings, and hence, the number of mismatching substrings provides an estimate of the edit distance. More formally, both methodologies map the inputs x and y into sets Tₓ, and T_{y}, respectively; these sets include pairs of the form (γ, i), where γ is a sufficiently long substring and i is a special “encoding” of the position at which the substring begins. The encoding scheme has the property that nearby positions are likely to share the same encoding. A pair (y,i)∈Tₓ∩T_{y} represents substrings of x and of y that match; i.e., they are identical (in terms of contents) and they occur at nearby positions in x and in y.

A pair (γ,i)∈(Tₓ\T_{y})∪(T_{y}\Tₓ) represents a substring that cannot be matched using a small number of edit operations. This gives rise to a natural reduction from the task of estimating edit distance between x and y to that of estimating the Hamming distance between the characteristic vectors u and v of Tₓ and T_{y}, respectively. Again, the Hamming distance (HD) between two strings x,y∈{0,1}ⁿ is defined as HD(x,y)=^{def}|{i∈[n]:x(i)≠y(i)}|.

The realizations of the above idea in the two methodologies are quite different, mainly due to the implementation of the “position encoding”. The first methodology is operable for arbitrary input strings. In this methodology, Tₓ and T_{y} include all of the (overlapping) substrings of a suitable length B=B(n,k) of x and y, respectively. Again, n is the length of the input strings and k is the gap parameter. The position of each substring is encoded by rounding the position down to the nearest multiple of an appropriately chosen integer D=D(n,k). A tradeoff between B and D implies that the best worst-case guarantees are obtained for choice of parameters of B=Θ(n^{2/3}/k^{1/3}) and D=n/B, which results in a methodology that can solve the k vs. O(kB) gap edit distance problem. Of course, the parameters B and D could be set differently depending on the context (e.g., using knowledge about the specific application domain).

The second methodology, which is operable for mildly non-repetitive strings, introduces a more sophisticated “position encoding” method, based on selecting a set of “anchors” from x and from y in a coordinated way. Anchors are substrings that are unique within a certain window and appear in both x and y in that window. Suppose x and y have an alignment that uses only a small number of edit operations. Then, a sufficiently short substring chosen at random from any sufficiently long window in x is unlikely to contain any edit operation, and thus has to match exactly a corresponding substring in y within the same window. This pair of substrings forms anchors. The key idea is that the coordinated selection of anchors can be done without Alice and Bob communicating with each other, but rather by using the shared random coins. Once this is accomplished, the anchors induce a natural partitioning of x and y into disjoint substrings. Tₓ and T_{y} then include these substrings, with the position of each substring being encoded by the number of anchors that precede it. This technique may be more accurate as it is guaranteed to solve a much smaller gap edit distance problems, in which the gap is independent of n.

A technical obstacle in both methodologies is that the Hamming distance instances to which the problem is reduced are exponentially long. While this still leads to constant size sketches, the running time needed to produce these sketches may be prohibitive. The embodiments of the invention observe that the Hamming distance instances produced above are always of Hamming weight at most n. Next, a sketching method is described that approximates the Hamming distance, but runs in time proportional to the Hamming weight of the strings.

For any ε>0 and k=k(n), there is an efficient sketching methodology that solves the k vs. (1+α)k gap Hamming distance problem in binary strings of length n, with a sketch of size O(1/ε²). If the set of non-zero coordinates of each input string can be computed in time t, then Alice and Bob run in O(ε⁻³t log n) time.

For any 0≦k<\sqrt{n}, there exists a quasi-linear time sketching methodology that solves the k vs. Ω((kn)^{2/3}) gap edit distance problem using sketches of size O(1). The methodology follows the general scheme described in the overview above. What is left is to formally describe how the sets Tₓ and T_{y} are constructed. For simplicity of exposition, the embodiments of the invention assume n and k are powers of two with an exponent that is a multiple of three (e.g. by padding with zeros). Next, what is described now how Alice creates the set Tₓ. Bob's methodology is analogous. Let B=n^{2/3}/(2k^{1/3}) and let D=n/B. For each position i∈[n], let DIV(i)=^{def}└i/D┘(which is proportional to the largest multiple of D that is at most i). Tₓ is the set of pairs (x[i . . . , i+B−1], DIV(i))for i=1, . . . , n−B+1. Next, the coordinates of u (and similarly v) are associated with pairs of the form (γ,j), where γ is a bitstring of length B and j is an integer between 0 and

$$\frac{n}{D} .$$

The Hamming distance sketch of the vectors u and v (these are the characteristic vectors of Tₓ and T_{y}, respectively) is tuned to determine whether HD(u,v)≦4kB or HD(u,v)>8kB with (large) constant probability of error. The referee, upon receiving the sketches from Alice and Bob, decides that ED(x, y)≦k if he finds that HD(u,v)<4kB. Otherwise, he decides that ED(x, y)≧13(kn)^{2/3}. The reasoning behind this decision is that there is a direct connection (which can be verified mathematically) between ED(x,y) and HD(u,v) as follows: (i) if ED(x, y)≦k, then HD(u,v)≦4kB; and (ii) if ED(x,y)≧13(kn)^{2/3}, then HD(u,v)≧8kB.

For example, for any 1≦t<n and for any 1≦k<O(\sqrt{n/t}, there exists a polynomial-time efficient sketching methodology that solves the k vs. Ω(tk²) gap edit distance problem for substantially (t, tk)-non-repetitive strings using sketches of size O(1). What is left to do is to specify how the sets Tₓ and T_{y} are constructed. Let x,y∈{0,1}ⁿ be two (t, tk)-non-repetitive input strings. Alice creates the set Tₓ as follows: Bob's methodology is similar. First, she uses the shared randomness to compute a Karp-Rabin fingerprint of size O(log n) (or a similar alternative technique) for every substring of x of length t. This can be done in O(n) time. The embodiments of the invention let ƒ(•) denote the chosen fingerprint function. Let λ>0 be a sufficiently large constant that will be tuned later.

Next, Alice selects a sequence of disjoint substrings a₁ , . . . , aᵣ_{ₓ} of x, called “anchors”, iteratively as follows. She maintains a sliding window of length W=^{def}λtk over her string. Let c denote the left endpoint of the sliding window; initially, c is set to 1. At the i-th step, Alice considers the W substrings of length t whose starting position lies in the interval [c+W . . . , c+2W−1]. For j=1 , . . . , W, let sᵢⱼ=x[c+j+W−1 . . . , c+j+W+t−2] be the j-th substring. Using the shared randomness, Alice picks a random permutation IIᵢ on the space {0,1}^{O(log n)} and sets the anchor aᵢ to be a substring s_{i,l} whose fingerprint is minimal according to IIᵢ; i.e., IIᵢ(ƒ(s_{i,l}))=min{IIᵢ(ƒ(s_{i,1})), . . . , IIᵢ(ƒ(s_{i,w}))}. She then slides the window by setting c to the position immediately following the anchor, i.e., c←c+l+W−1+t. If this new value of c is at most n−(2W+t), Alice starts a new iteration. Otherwise, she stops, letting rₓ be the number of anchors she collected.

For i∈[rₓ], let φ₁, be the substring starting at the position immediately after the last character of anchor aᵢ₋ₗ and ending at the last character of aᵢ. For this definition to make sense for i=1, define a₀ to be the empty string, and consider it as if it is located at position 0, hence φ₁. starts at position 1. Finally, Tₓ is the set of pairs (φᵢ, i) for all i∈[rₓ]. Bob constructs T_{y} analogously by choosing anchors β₁, . . . , β_{ry} using the same random permutations IIᵢ. The Hamming distance sketch for the strings u, v (the incidence vectors of Tₓ, T_{y}) is tuned to solve the 3k vs. 6k gap Hamming distance problem with a probability of error of at most 1/12. The referee, upon receiving the two sketches, decides that ED(x, y)≦k if he finds that HD(u, v)≦3k, and decides that ED(x, y)>φ(tk²) otherwise. Again, the reasoning behind this decision is that there is a direct connection (which can be verified mathematically) between ED(x,y) and HD(u,v) as follows: (i) if ED(x,y)≦k, then HD(u,v)<3k with probability≧⅚; (ii) if HD(u, v)≦6k, then ED(x, y)<O(tk²).

Next, quasi-linear time methodologies for edit distance gap problems are developed in accordance with the embodiments of the invention. The edit graph G_{E} is a well-known representation of the edit distance by means of a directed graph. In essence, a source-to-sink shortest path in G_{E} is equivalent to the natural dynamic programming methodology. A graph G is defined, which can be viewed as a lossy compression of G_{E}—the shortest path in G provides an approximation to the edit distance. Each edge in G corresponds with the edit distance between substrings, unlike in G_{E} where each edge corresponds to at most a single edit operation. The advantage of G is its structure allows one to accelerate the shortest path computation by handling multiple edges simultaneously. The latter turns out to be essentially an instance of a problem known as the edit pattern matching problem.

The graph G is defined as follows. Let B be a parameter that will determine the size of substrings used in the methodology; assume that B divides n. Let k be a parameter that can be thought of as the current guess for ED(x,y). Each vertex in G corresponds to a pair (i, s) where i=jB, for some j∈[0 . . . , n/B] and s∈[−k . . . , k]; this vertex is closely related to the edit distance between the substrings x[1 . . . , i] and y[1 . . . , i+s] (s denotes the amount by which the embodiments of the invention extend/diminishy with respect to x). There is a directed edge e from (i′,s′) to (i, s) ifand only ifeither (1)i′=i and |s′−s|=1, or (2)i′=i−B and s′=s. The edge e has an associated weight w(e) which equals 1 if i′=i and |s′−s|=1. For the other case when i′=i−B and s′=s, the embodiments of the invention allow some flexibility in setting the value of w(e). In particular, given an approximation parameter c, then w(e) can be any value such that:
w(e)/c≦ED(x[i′+1 . . . , i],y[i′+1+s . . . , i +s])≦w(e) .

For any path P in G, let the weight w(P) of the path P equal the sum of the weights of the edges in P. Let T equal the weight of the shortest path from (0,0) to (n, 0). The following implications (which can be verified mathematically) demonstrate that the value of T can be used to solve the k vs. l edit distance gap problem for a suitable l=l(k,c): (i), T≧ED(x,y); and (ii) T≦(2c+2)ED(x,y).

Next, the process of how to compute the shortest path in G from (0, 0) to (n, 0) efficiently is shown. Fix an i and consider the set of edges from (i, s) to (i+B, s) for all s. These represent the approximate edit distances between x[i+1 . . . , i +B] and every substring of y[i+1−k . . . , i+B+k] of length B. If one simultaneously computes all these weights efficiently, then it is conceivable that the shortest path methodology can also be implemented efficiently. This is formalized as a separate problem below.

Definition (Edit pattern matching problem). Given a pattern string P of length p and a text string T of length t≧p, the c(p,t)-edit pattern matching problem, for some c=c(p,t)≧1, is to produce numbers d₁, d₂ , . . . , dₜ₋ₚ₊₁ such that dᵢ/c<ED(P, T[i . . , i+p−1])≦dᵢ for all i. Next, suppose there is an methodology that can solve the c(p, t)-edit pattern matching problem in time TIME(p, t). Then, given two strings x and y of length n, and the corresponding graph G with parameter B, the shortest path in the graph G can be used to solve the k versus (2c(B, B+2k)+2)k edit distance gap problem, and it can be computed in time O((k+TIME(B,B+2k))n/B).

The implementation of the shortest path methodology proceeds in stages where the i-th stage computes the distance T(i,s) from (0,0) to (i, s) simultaneously for all s. The key idea is to reduce this problem to computing single-source shortest paths on a graph with O(k) edges. Assume that T(i−B, s) has been computed for all values of s. It is shown how to compute T(i,s) for all s in time O(k+TIME(B, B+2k)); the claim on the overall running time of the methodology follows easily. Any shortest path to (i, s) is attained by a shortest path from (0, 0) to (i−B,s′), for some s′, followed by the edge from (i−B, s′) to (i,s′), and then followed by the path from (i,s′) to (i, s). Consider the following graph H of at most 2k+2 nodes with a start node u and a node vₛ for every S∈[−k,k]. There is an edge between vₛ and vᵣ with weight 1 if and only if |s−r|=1; there is an edge from u to vₛ with weight T(i−B, s)+w((i+B, s), (i, s)). This graph can be constructed in time O(k+TIME(B, B+2k)). It can be verified that the shortest path from u to vₛ equals T(i, s). This can he implemented using the well-known Dijkstra shortest path methodology in time O(k log k). A direct implementation is also possible by sorting the edges from u to v_{S} in non-decreasing order of weight; the values T(i, s) can be calculated by carefully eliminating the edges, each one in O(1) time.

As an application of the above, suppose one runs a pattern matching methodology which outputs dᵢ=0 if P=T[i . . . , i+p−1] and (dᵢ=p otherwise; thus, c(p, t)=p. By pre-computing the Karp-Rabin fingerprints of all blocks of length B in x and y in time O(n), one may obtain such a methodology for edit pattern matching that runs in time O(k). Consequently, there is a methodology for the k vs. (2B+2)k edit distance gap problem that runs in time O(kn/B+n). In particular there is a quasi-linear-time methodology to distinguish between k and O(k²).

For the second application, given a parameter k, the goal is to output for each i∈[1 . . . , t−p+1] whether there is a substring T[i . . . , j], for some j, such that ED(P,T[i . . . , j]) is at most k. The conventional methodology runs in time O(k⁴·t/p+t+p). The methodology can be easily modified to obtain a quasi-linear time methodology for edit pattern matching whose approximation parameter is c=p^{3/4}. Applying the above with B=k, one obtains a methodology that solves the k vs. k^{7/4} edit distance gap problem running in quasi-linear-time. For substantially non-repetitive strings, one can get a stronger \sqrt{p}-approximation methodology for the edit pattern matching problem that runs in quasi-linear-time. Now B=k implies that the k vs. k^{3/2} edit distance gap problem can be solved in quasi-linear-time if at least one of the pair of input strings is (k, O(\sqrt{k})-non-repetitive. Those skilled in the art would readily acknowledge that the above yields approximation methodologies for edit distance with factors n^{3/7} and n^{1/3}, respectively.

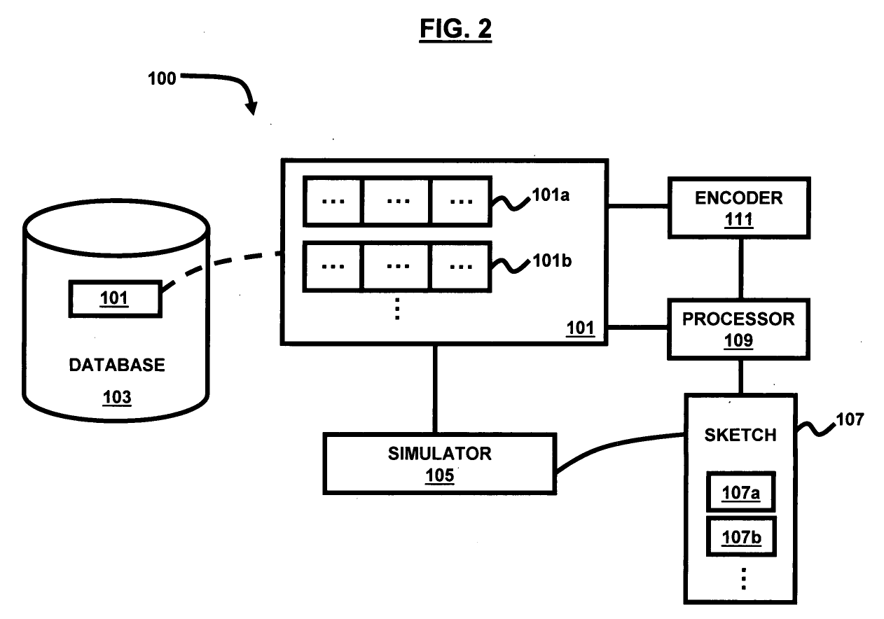

FIG. 2 illustrates a block diagram of a system 100 of approximating edit distance for a set of character strings 101 in a database 103 according to an embodiment of the invention, wherein the system 100 comprises a simulator 105 adapted to produce a representative sketch 107 for each of the character strings 101; and a processor 109 adapted to approximate an edit distance between two selected character strings 101a, 101b based only on the representative sketch 107 for each of the selected character strings 101a, 101b. In one embodiment the character strings 101 comprise text, wherein the system 100 further comprises an encoder 111 adapted to encode positions of substrings in the text using anchors, wherein the anchors comprise identical substrings occurring in two input character strings at a nearby position. The processor 109 may be further adapted to create substrings (not shown) from each of the character strings 101a, 101b; identify anchors (not shown) in a particular character string 101a or 101b; identify a start position of the substrings of the particular character string 101a or 101b according to the anchors; identify a set of substrings according to the start position; encode the set of substrings to produce the representative sketch 107; and use a Hamming distance between encodings of the two selected character strings 101a, 101b to approximate the edit distance between the two selected character strings 101a, 101b.

Alternatively, the processor 109 may be further adapted to create substrings from each of the character strings; identify a start position of the substrings of the particular character string; encode a start position of the substrings of the particular character string 101a or 101b by rounding a numeric value of the start position to a nearest multiple of a predetermined number; identify a set of substrings according to the start position; encode the set of substrings to produce the representative sketch 107; and use a Hanmming distance between encodings of the two selected character strings 101a, 101b to approximate the edit distance between the two selected character strings 101a, 101b.

Preferably the encoder 111 is adapted to use a set of anchors in a correlated manner, wherein character strings 101 with a sufficiently small edit distance are likely to use a same sequence of anchors. In one embodiment the character strings 101 are substantially non-repetitive. Preferably, the representative sketch 107a of a first character string 101a is constructed absent knowledge of a second character string 101b. Moreover, a size of the representative sketch 107 may be constant. When the character strings 101 comprise text, the processor 109 is adapted to approximate the edit distance between two selected character strings 101a, 101b to within a constant factor on the order of n^{3/7}, wherein n comprises a size of the text. Additionally, in another embodiment when the character strings 101 comprise text, the processor 109 is adapted to approximate the edit distance between two selected character strings 101a, 101b to within a factor on the order of n^{1/3}, wherein n comprises a size of the text.

The embodiments of the invention can take the form of an entirely hardware embodiment, an entirely software embodiment or an embodiment including both hardware and software elements. In a preferred embodiment, the invention is implemented in software, which includes but is not limited to firmware, resident software, microcode, etc.

Furthermore, the embodiments of the invention can take the form of a computer program product accessible from a computer-usable or computer-readable medium providing program code for use by or in connection with a computer or any instruction execution system. For the purposes of this description, a computer-usable or computer readable medium can be any apparatus that can comprise, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk—read only memory (CD-ROM), compact disk—read/write (CD-R/W) and DVD.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output (I/O) devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modem and Ethernet cards are just a few of the currently available types of network adapters.

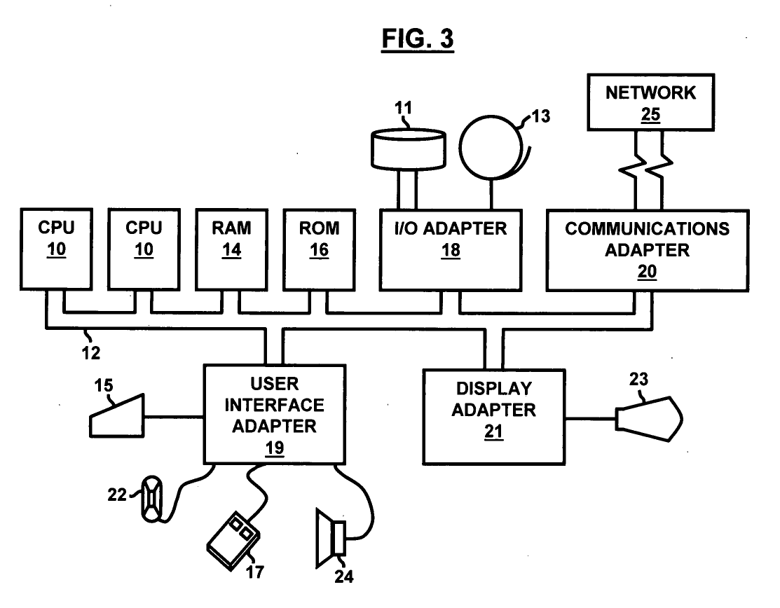

A representative hardware environment for practicing the embodiments of the invention is depicted in FIG. 3. This schematic drawing illustrates a hardware configuration of an information handling/computer system in accordance with the embodiments of the invention. The system comprises at least one processor or central processing unit (CPU) 10. The CPUs 10 are interconnected via system bus 12 to various devices such as a random access memory (RAM) 14, read-only memory (ROM) 16, and an input/output (I/O) adapter 18. The I/O adapter 18 can connect to peripheral devices, such as disk units 11 and tape drives 13, or other program storage devices that are readable by the system. The system can read the inventive instructions on the program storage devices and follow these instructions to execute the methodology of the embodiments of the invention. The system further includes a user interface adapter 19 that connects a keyboard 15, mouse 17, speaker 24, microphone 22, and/or other user interface devices such as a touch screen device (not shown) to the bus 12 to gather user input. Additionally, a communication adapter 20 connects the bus 12 to a data processing network 25, and a display adapter 21 connects the bus 12 to a display device 23 which may be embodied as an output device such as a monitor, printer, or transmitter, for example.

The embodiments of the invention develop methodologies that solve gap versions of the edit distance problem: given two strings of length n with the premise that their edit distance is either at most k or greater than l, and decides which of the two holds. The embodiments of the invention present two sketching methodologies for gap versions of edit distance. The first methodology solves the k vs. (kn)^{2/3} gap problem, using a constant size sketch. A more involved methodology solves the stronger k vs. 1 gap problem, where l can be as small as O(k²)-still with a constant sketch-but operates for strings that are substantially “non-repetitive”. Again, mildly repetitive strings may occur.

Finally, the embodiments of the invention develop an n^{3/7}-approximation quasi-linear time methodology for edit distance, improving the previous conventional best factor of n^{3/4}; if the input strings are assumed to be substantially non-repetitive, then the approximation factor can be strengthened to n^{1/3}.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. A method of approximating edit distance for a set of character strings in a database, said method comprising:
producing a representative sketch for each of said character strings; and
approximating an edit distance between two selected character strings based only on said representative sketch for each of said selected character strings.

2. The method of claim 1, wherein said method further comprises:
creating substrings from each of said character strings;
identifying anchors in a particular character string;
identifying a start position of said substrings of said particular character string according to said anchors;
identifying a set of substrings according to said start position;
encoding said set of substrings to produce said representative sketch; and
using a Hamming distance between encodings of said two selected character strings to approximate said edit distance between said two selected character strings.

3. The method of claim 1, wherein said method further comprises:
creating substrings from each of said character strings;
encoding a start position of said substrings of said particular character string by rounding a numeric value of said start position to a nearest multiple of a predetermined number;
identifying a set of substrings according to said start position;
encoding said set of substrings to produce said representative sketch; and
using a Hamming distance between encodings of said two selected character strings to approximate said edit distance between said two selected character strings.

4. The method of claim 1, wherein said character strings comprise text, and wherein said method further comprises encoding positions of substrings in said text using anchors, wherein said anchors comprise identical substrings occurring in two input character strings at a nearby position.

5. The method of claim 4, further comprising using a set of anchors in a correlated manner, wherein character strings with a sufficiently small edit distance are likely to use a same sequence of anchors.

6. The method of claim 1, wherein said character strings are substantially non-repetitive.

7. The method of claim 1, wherein said representative sketch of a first character string is constructed absent knowledge of a second character string.

8. The method of claim 1, wherein a size of said representative sketch is constant.

9. The method of claim 1, wherein said character strings comprise text, and wherein said method further comprises approximating said edit distance between two selected character strings to within a constant factor on the order of n^{3/7}, wherein n comprises a size of said text.

10. The method of claim 6, wherein said character strings comprise text, and wherein said method further comprises approximating said edit distance between two selected character strings to within a factor on the order of n^{1/3}, wherein n comprises a size of said text.

11. A program storage device readable by computer, tangibly embodying a program of instructions executable by said computer to perform a method of approximating edit distance for a set of character strings in a database, said method comprising:
producing a representative sketch for each of said character strings; and
approximating an edit distance between two selected character strings based only on said representative sketch for each of said selected character strings.

12. The program storage device of claim 11, wherein said method further comprises:
creating substrings from each of said character strings;
identifying anchors in a particular character string;
identifying a start position of said substrings of said particular character string according to said anchors;
identifying a set of substrings according to said start position;
encoding said set of substrings to produce said representative sketch; and
using a Hamming distance between encodings of said two selected character strings to approximate said edit distance between said two selected character strings.

13. The program storage device of claim 11, wherein said method further comprises:
creating substrings from each of said character strings;
encoding a start position of said substrings of said particular character string by rounding a numeric value of said start position to a nearest multiple of a predetermined number;
identifying a set of substrings according to said start position;
encoding said set of substrings to produce said representative sketch; and
using a Hamming distance between encodings of said two selected character strings to approximate said edit distance between said two selected character strings.

14. The program storage device of claim 11, wherein said character strings comprise text, and wherein said method further comprises encoding positions of substrings in said text using anchors, wherein said anchors comprise identical substrings occurring in two input character strings at a nearby position.

15. The program storage device of claim 14, wherein said method further comprises using a set of anchors in a correlated manner, wherein character strings with a sufficiently small edit distance are likely to use a same sequence of anchors.

16. The program storage device of claim 11, wherein said character strings are substantially non-repetitive.

17. The program storage device of claim 11, wherein said representative sketch of a first character string is constructed absent knowledge of a second character string.

18. The program storage device of claim 11, wherein a size of said representative sketch is constant.

19. The program storage device of claim 11, wherein said character strings comprise text, and wherein said method further comprises approximating said edit distance between two selected character strings to within a constant factor on the order of n^{3/7}, wherein n comprises a size of said text.

20. The program storage device of claim 16, wherein said character strings comprise text, and wherein said method further comprises approximating said edit distance between two selected character strings to within a factor on the order of n^{1/3}, wherein n comprises a size of said text.

21. A system of approximating edit distance for a set of character strings in a database, said system comprising:
a simulator adapted to produce a representative sketch for each of said character strings; and
a processor adapted to approximate an edit distance between two selected character strings based only on said representative sketch for each of said selected character strings.

22. The system of claim 21, wherein said processor is further adapted to:
create substrings from each of said character strings;
identify anchors in a particular character string;
identify a start position of said substrings of said particular character string according to said anchors;
identify a set of substrings according to said start position;
encode said set of substrings to produce said representative sketch; and
use a Hamming distance between encodings of said two selected character strings to approximate said edit distance between said two selected character strings.

23. The system of claim 21, wherein said processor is further adapted to:
create substrings from each of said character strings;
encode a start position of said substrings of said particular character string by rounding a numeric value of said start position to a nearest multiple of a predetermined number;
identify a set of substrings according to said start position;
encode said set of substrings to produce said representative sketch; and
use a Hamming distance between encodings of said two selected character strings to approximate said edit distance between said two selected character strings.

24. The system of claim 21, wherein said character strings comprise text, and wherein said system further comprises an encoder adapted to encode positions of substrings in said text using anchors, wherein said anchors comprise identical substrings occurring in two input character strings at a nearby position.

25. The system of claim 24, wherein said encoder is adapted to use a set of anchors in a correlated manner, wherein character strings with a sufficiently small edit distance are likely to use a same sequence of anchors.

26. The system of claim 21, wherein said character strings are substantially non-repetitive.

27. The system of claim 21, wherein said representative sketch of a first character string is constructed absent knowledge of a second character string.

28. The system of claim 21, wherein a size of said representative sketch is constant.

29. The system of claim 21, wherein said character strings comprise text, and wherein said processor is adapted to approximate said edit distance between two selected character strings to within a constant factor on the order of n^{3/7}, wherein n comprises a size of said text.

30. The system of claim 26, wherein said character strings comprise text, and wherein said processor is adapted to approximate said edit distance between two selected character strings to within a factor on the order of n^{1/3}, wherein n comprises a size of said text.
